(19) United States
(12) Patent Application Publication
(10) Pub. No.: US 2016/0125955 A1
(43) Pub. Date: May 5, 2016

(54) Shift Register, Driving Method Thereof and Gate Driving Circuit

(71) Applicants: BOE Technology Group Co., Ltd., Beijing (CN); Beijing BOE Optoelectronics Technology Co., Ltd., Beijing (CN)

(72) Inventor: Fengchun Pang, Beijing (CN)

(21) Appl. No.: 14/806,872

(22) Filed: Jul. 23, 2015

(30) Foreign Application Priority Data
Oct. 30, 2014 (CN) 201410598337.7

(51) Int. Cl. G11C 19/28

(52) U.S. Cl. CPC G11C 19/287

(57) ABSTRACT

A shift register, driving method thereof and a gate driving circuit are disclosed, wherein the shift register comprises an input module, a reset module, a first output module, a second output module and a control module. The shift register uses the first clock signal to control the second node, and then controls the signal output by the signal output terminal by alternate high/low levels of the second node and the second clock signal, such that the signal output terminal can always output signals to eliminate noises and stabilize row output signals. In addition, since the second node has alternate high/low levels, the life span of the shift register can be protected.

This application claims priority to Chinese Patent Application No. 201410598337.7 filed on Oct. 30, 2014. The present application claims priority to and the benefit of the above-identified application and is incorporated herein in its entirety.

### TECHNICAL FIELD OF THE DISCLOSURE

The present disclosure relates to a shift register, driving method thereof and a gate driving circuit.

### BACKGROUND

In a thin film transistor (TFT) display, usually, a gate driving apparatus provides gate driving signals to gates of TFTs in a pixel area. The gate driving apparatus can be formed on a array substrate of a liquid crystal display (LCD) by an array process, i.e., a gate driver on array (GOA) process. Such an integration process not only reduces cost, but also can achieve a beautiful design in which two sides of the liquid crystal panel is symmetric. At the same time, it saves wiring space of fan-out and bonding area of a gate integrated circuit (IC) such that a design of narrow frame can be achieved. In addition, such an integration process can save bonding process in the gate scan line direction such as to improve productivity and yield.

Currently, in existing gate driving circuits, mostly, one clock signal is used to control a pull-down node which is then used to control the pull-down of a pull-up node and a signal output terminal. However, the duty ratio of the pull-down node is 50%; therefore, the signal output terminal Output is pulled down during half time of a scan period, and is floated during the other half time, such that the noise of signals output by the signal output terminal is large. However, currently, some gate driving circuits in existing solutions use a voltage of a direct current (DC) source to control the pull-down node to cause the pull-down node always to be at a high level state, such that the pull-up node and the signal output terminal are always be pulled down. However, this is detrimental to the life span of TFTs.

### SUMMARY

At least one embodiment of the present disclosure provides a shift register, driving method thereof and a gate driving circuit, which can reduce noises of signals output by signal output terminals while ensuring the life span of TFTs.

Therefore, at least one embodiment of the present disclosure provides a shift register comprising an input module, a reset module, a first output module, a second output module and a control module; wherein

the input module is configured to provide a first reference voltage to a first node under the control of an input signal; the first node is a connection point of the input module, the reset module, the first output module and the control module;

the reset module is configured to provide a second reference voltage to the first node under the control of a reset signal;

the first output module is configured to provide a first clock signal to a signal output terminal when the voltage of the first node is a first voltage;

the second output module is configured to provide a voltage of a DC voltage source to a second node and the signal output terminal under the control of a second clock signal and provide the voltage of the DC voltage source to the signal output terminal when the voltage of the second node is the first voltage; the second node is a connection point of the second output module and the control module;

the control module is configured to cause the voltage of the first node to be a second voltage when the voltage of the second node is the first voltage, cause the voltage of the second node to be the second voltage when the voltage of the first node is the first voltage, and provide the first clock signal to the second node under the control of the first clock signal;

the first clock signal has an opposite phase to the second clock signal;

the first voltage is a high level voltage, the second voltage is a low level voltage, and the voltage of the DC voltage source is a low level voltage; or the first voltage is a low level voltage, the second voltage is a high level voltage, and the voltage of the DC voltage source is a high level voltage.

In one possible implementation, in the above shift register provided by at least one embodiment of the present disclosure, the control module comprises: a first control sub-module, a second control sub-module and a third control sub-module;

the first control sub-module is configured to provide the voltage of the DC voltage source to the first node when the voltage of the second node is the first voltage;

the second control sub-module is configured to provide the voltage of the DC voltage source to the second node when the voltage of the first node is the first voltage;

the third control sub-module is configured to provide the first clock signal to the second node under the control of the first clock signal.

In one possible implementation, in the above shift register provided by at least one embodiment of the present disclosure, the input module comprises a first switch transistor;

a gate of the first switch transistor is connected with the input signal, a source of the first switch transistor is connected with the first reference voltage, and a drain of the first switch transistor is connected to the first node.

In one possible implementation, in the above shift register provided by at least one embodiment of the present disclosure, the reset module comprises a second switch transistor;

a gate of the second switch transistor is connected with the reset signal, a source of the second switch transistor is connected with the second reference voltage, and a drain of the second switch transistor is connected to the first node.

In one possible implementation, in the above shift register provided by at least one embodiment of the present disclosure, the first output module comprises a third switch transistor and a capacitor;

a gate of the third switch transistor is connected to the first node, a source of the third switch transistor is connected with the first clock signal, and a drain of the third switch transistor is connected to the signal output terminal;

the capacitor is connected between the gate and the drain of the third switch transistor.

In one possible implementation, in the above shift register provided by at least one embodiment of the present disclosure, the second output module comprises a fourth switch transistor, a fifth switch transistor and a sixth switch transistor;

a gate of the fourth switch transistor is connected with the second clock signal, a source of the fourth transistor is connected to the DC voltage source, and a drain of the fourth switch transistor is connected to the signal output terminal;

a gate of the fifth switch transistor is connected with the second clock signal, a source of the fifth switch transistor is connected to the DC voltage source, and a drain of the fifth switch transistor is connected to the second node;

a gate of the sixth switch transistor is connected to the second node, a source of the sixth switch transistor is connected to the DC voltage source, a drain of the sixth switch transistor is connected to the signal output terminal.

In one possible implementation, in the above shift register provided by at least one embodiment of the present disclosure, the first control sub-module comprises a seventh switch transistor;

a gate of the seventh switch transistor is connected to the second node, a source of the seventh switch transistor is connected to the DC voltage source, and a drain of the seventh switch transistor is connected to the first node

In one possible implementation, in the above shift register provided by at least one embodiment of the present disclosure, the second control sub-module comprises an eighth switch transistor;

a gate of the eighth switch transistor is connected to the first node, a source of the eighth switch transistor is connected to the DC voltage source, a drain of the eighth switch transistor is connected to the second node.

In one possible implementation, in the above shift register provided by at least one embodiment of the present disclosure, the third control sub-module comprises a ninth switch transistor;

both a gate and a source of the ninth transistor are connected with the first clock signal, a drain of the ninth transistor is connected to the second node.

In one possible implementation, in the above shift register provided by at least one embodiment of the present disclosure, when the voltage of the DC voltage source is a low level voltage, all the switch transistors are N type transistors; and

when the voltage of the DC voltage source is a high level voltage, all the switch transistors are P type transistors.

Accordingly, at least one embodiment of the present disclosure also provides a driving method of any shift register as described in the above, comprising:

at a first phase, the input module providing the first reference voltage to the first node under the control of the input signal; the first output module providing the first clock signal to the signal output terminal under the control of the first node; the second output module providing the voltage of the DC voltage source to the second node and the signal output terminal under the control of the second clock signal; the control module causing the voltage of the second node to be the second voltage under the control of the first node;

at a second phase, the first output module providing the first clock signal to the signal output terminal; the control module providing the first clock signal to the second node under the control of the first clock signal, and causing the voltage of the second node to be the second voltage when the voltage of the first node is the first voltage;

at a third phase, the reset module providing the second reference voltage to the first node under the control of the reset signal; the second output module providing the voltage of the DC voltage source to the second node and the signal output terminal under the control of the second clock signal;

at a fourth phase, the control module providing the first clock signal to the second node under the control of the first clock signal, and causing the voltage of the first node to be the second voltage when the voltage of the second node is the first voltage; the second output module providing the voltage of the DC voltage source to the signal output terminal under the control of the second node;

at a fifth phase, the second output module providing the voltage of the DC voltage source to the second node and the signal output terminal under the control of the second clock signal.

Accordingly, at least one embodiment of the present disclosure also provides a gate driving circuit comprising multiple shift registers of any type described above and provided by embodiments of the present disclosure which are connected in series; wherein

except the first stage of shift register, the signal output terminal of each stage of shift register inputs a reset signal to its adjacent previous stage of shift register;

except the last stage of shift register, the signal output terminal of each stage of shift register inputs an input signal to its adjacent next stage of shift register;

the input signal of the first stage of shift register is input by a frame start signal terminal, wherein

clock signals input into first clock signal terminals of two adjacent stages of shift register have opposite phases to each other, and clock signals input into second clock signal terminals of two adjacent stages of shift register have opposite phases to each other.

At least one embodiment of the present disclosure provides the above shift register, driving method thereof and the gate driving circuit, wherein the shift register comprises an input module, a reset module, a first output module, a second output module and a control module. The input module is configured to provide a first reference voltage to a first node under the control of an input signal; the reset module is configured to provide a second reference voltage to the first node under the control of a reset signal; the first output module is configured to provide a first clock signal to a signal output terminal when the voltage of the first node is a first voltage; the second output module is configured to provide a voltage of a DC voltage source to a second node and the signal output terminal under the control of a second clock signal and provide the voltage of the DC voltage source to the signal output terminal when the voltage of the second node is the first voltage; the control module is configured to cause the voltage of the first node to be a second voltage when the voltage of the second node is the first voltage, cause the voltage of the second node to be the second voltage when the voltage of the first node is the first voltage, and provide the first clock signal to the second node under the control of the first clock signal. The shift register uses the first clock signal to control the second node, and controls the signal output by the signal output terminal by alternate high/low levels of the second node and the second clock signal, such that the signal output terminal can always output signals to eliminate noises and stabilize row output signals. In addition, since the second node has alternate high/low levels, the life span of the shift register can be protected.

### BRIEF DESCRIPTION OF THE DRAWINGS

FIG. 1 is a schematic diagram of structure of a shift register provided by an embodiment of the present disclosure;

FIG. 2 is a schematic diagram of structure of a shift register provided by an embodiment of the present disclosure;

FIG. 3a is a circuit time sequence diagram during forward scan of a shift register provided by an embodiment of the present disclosure;

FIG. 3b is a circuit time sequence diagram during reverse scan of a shift register provided by an embodiment of the present disclosure;

FIG. 4a is a circuit time sequence diagram during forward scan of a shift register provided by an embodiment of the present disclosure;

FIG. 4b is a circuit time sequence diagram during reverse scan of a shift register provided by an embodiment of the present disclosure;

FIG. 5a is a schematic diagram of detailed structure of a shift register provided by an embodiment of the present disclosure with all transistors being P type transistors;

FIG. 5b is a schematic diagram of detailed structure of a shift register provided by an embodiment of the present disclosure with all transistors being N type transistors;

FIG. 6a is a schematic diagram of detailed structure of a shift register provided by an embodiment of the present disclosure with all transistors being P type transistors;

FIG. 6b is a schematic diagram of detailed structure of a shift register provided by an embodiment of the present disclosure with all transistors being N type transistors;

FIG. 7 is a schematic flowchart of a driving method of a shift register provided by an embodiment of the present disclosure;

FIG. 8 is a schematic diagram of structure of a gate driving circuit provided by an embodiment of the present disclosure.

### DETAILED DESCRIPTION

In the following, specific implementations of shift registers, their driving methods, gate driving circuits and display apparatuses provided by embodiments of the present disclosure will be described in detail in connection with figures.

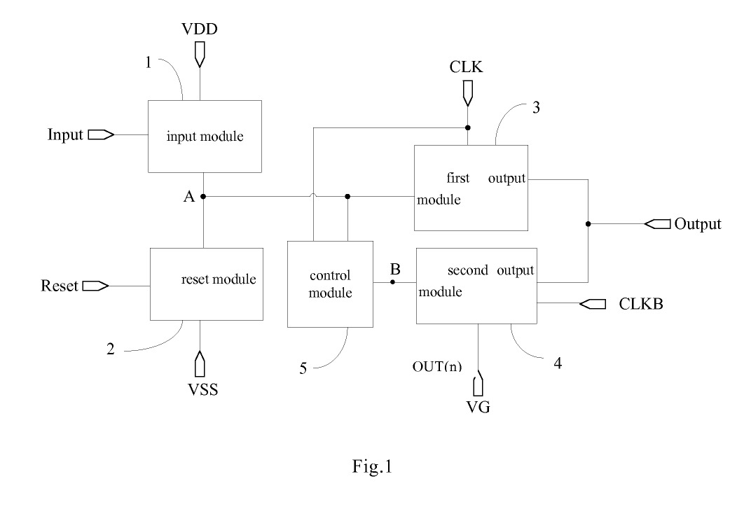

FIG. 1 is a schematic diagram of structure of a shift register provided by an embodiment of the present disclosure. A shift register provided by an embodiment of the present disclosure as shown in FIG. 1 comprises an input module 1, a reset module 2, a first output module 3, a second output module 4 and a control module 5.

The input module 1 is configured to provide a first reference voltage VDD to a first node A under the control of an input signal Input; the first node A is a connection point of the input module 1, the reset module 2, the first output module 3 and the control module 5.

The reset module 2 is configured to provide a second reference voltage VSS to the first node A under the control of a reset signal Reset.

The first output module 3 is configured to provide a first clock signal CLK to a signal output terminal Output when the voltage of the first node A is a first voltage.

The second output module 4 is configured to provide a voltage of a DC voltage source VG to a second node B and the signal output terminal Output under the control of a second clock signal CLKB and provide the voltage of the DC voltage source VG to the signal output terminal Output when the voltage of the second node B is the first voltage; the second node B is a connection point of the second output module 4 and the control module 5.

The control module 5 is configured to cause the voltage of the first node A to be a second voltage when the voltage of the second node B is the first voltage, cause the voltage of the second node B to be the second voltage when the voltage of the first node A is the first voltage, and provide the first clock signal CLK to the second node B under the control of the first clock signal CLK.

The first clock signal CLK has an opposite phase to the second clock signal CLKB.

The first voltage is a high level voltage, the second voltage is a low level voltage, and the voltage of the DC voltage source VG is a low level voltage; or the first voltage is a low level voltage, the second voltage is a high level voltage, and the voltage of the DC voltage source VG is a high level voltage.

The above shift register provided by an embodiment of the present disclosure comprises an input module, a reset module, a first output module, a second output module and a control module. The input module is configured to provide a first reference voltage to a first node under the control of an input signal; the reset module is configured to provide a second reference voltage to the first node under the control of a reset signal; the first output module is configured to provide a first clock signal to a signal output terminal when the voltage of the first node is a first voltage; the second output module is configured to provide a voltage of a DC voltage source to a second node and the signal output terminal under the control of a second clock signal and provide the voltage of the DC voltage source to the signal output terminal when the voltage of the second node is the first voltage; the control module is configured to cause the voltage of the first node to be a second voltage when the voltage of the second node is the first voltage, cause the voltage of the second node to be the second voltage when the voltage of the first node is the first voltage, and provide the first clock signal to the second node under the control of the first clock signal. The shift register uses the first clock signal to control the second node, and controls the signal output by the signal output terminal by alternate high/low levels of the second node and the second clock signal, such that the signal output terminal can always output signals to eliminate noises and stabilize row output signals. In addition, since the second node has alternate high/low levels, the life span of the shift register can be protected.

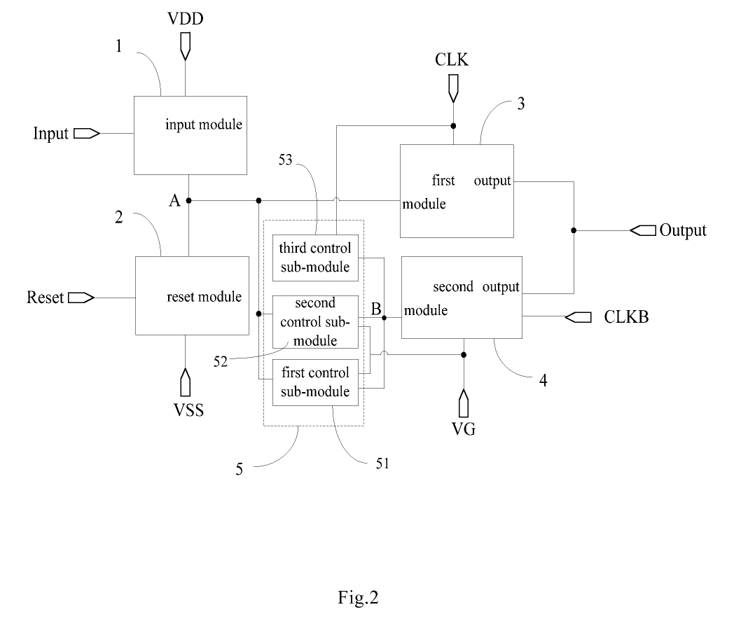

FIG. 2 is a schematic diagram of structure of a shift register provided by an embodiment of the present disclosure. Further, in the above shift register provided by an embodiment of the present disclosure, as shown in FIG. 2, the control module 5 comprises a first control sub-module 51, a second control sub-module 52 and a third control sub-module 53.

The first control sub-module 51 is configured to provide the voltage of the DC voltage source VG to the first node A when the voltage of the second node B is the first voltage.

The second control sub-module 52 is configured to provide the voltage of the DC voltage source VG to the second node B when the voltage of the first node A is the first voltage.

The third control sub-module 53 is configured to provide the first clock signal CLK to the second node B under the control of the first clock signal CLK.

It is noted that the above shift register provided by an embodiment of the present disclosure is a bi-directional scan register. If the voltage of the DC voltage source is a low level voltage, then during forward scan, the first reference voltage is a high level voltage, and the second reference voltage is a low level voltage, and during reverse scan, the input signal is taken as the reset signal, the reset signal is taken as the input signal, the first reference voltage is a low level voltage, and the reference voltage is a high level voltage. If the voltage of the DC voltage source is a high level voltage, then during forward scan, the first reference voltage is a low level voltage, and the second reference voltage is a high level voltage, and during reverse scan, the input signal is taken as the reset signal, the reset signal is taken as the input signal, the first reference voltage is a high level voltage, and the reference voltage is a low level voltage.

In the following, in connection with circuit time sequence diagrams, the operation principle of the above shift register provided by an embodiment of the present disclosure will be briefly described by examples that the voltage of the DC voltage source is a low level voltage and a high level voltage respectively.

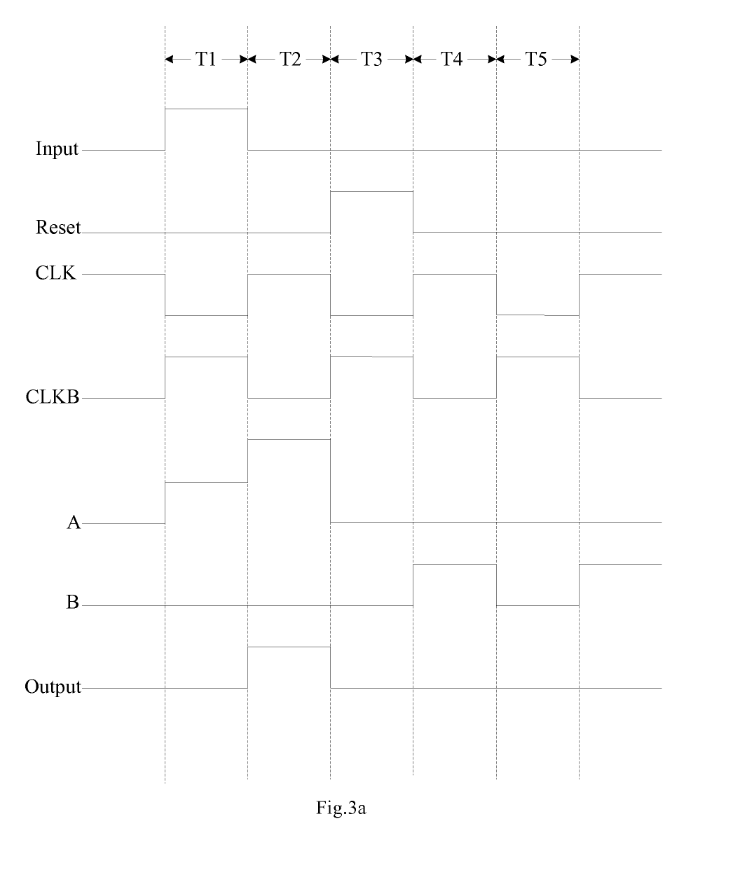

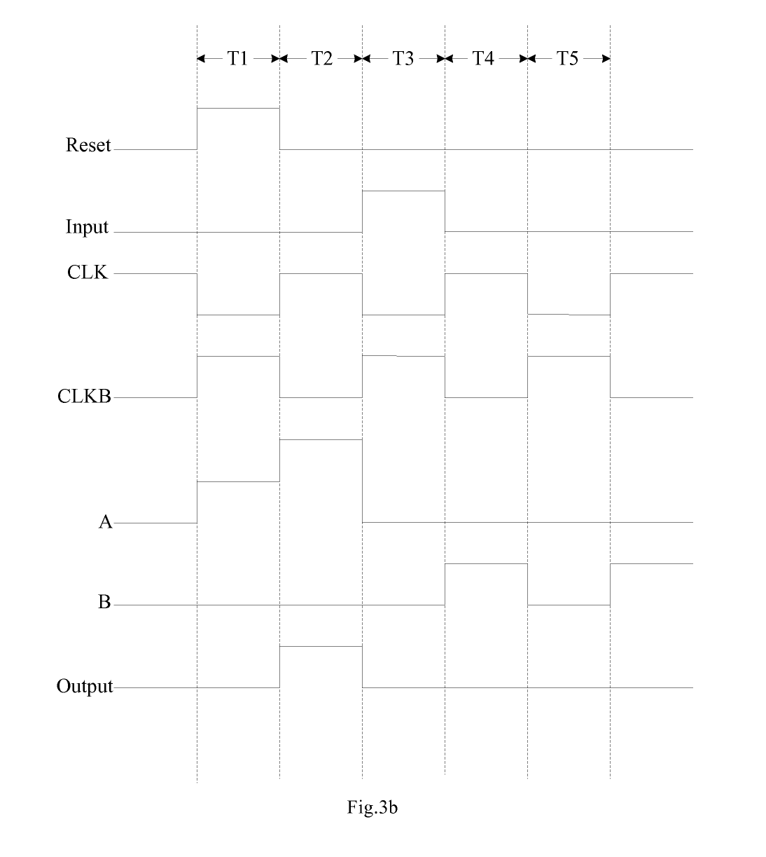

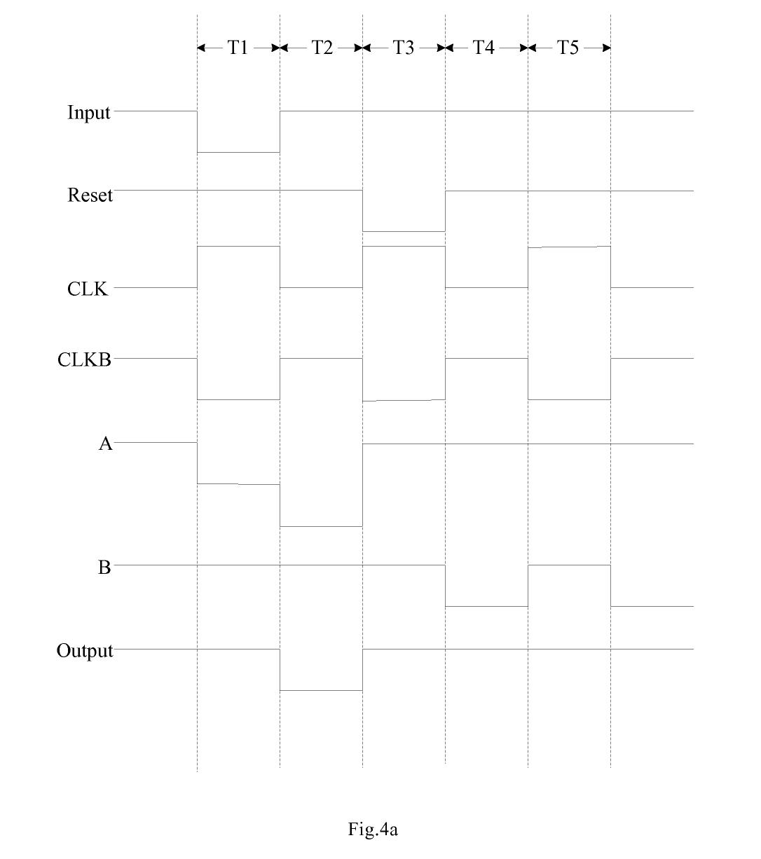

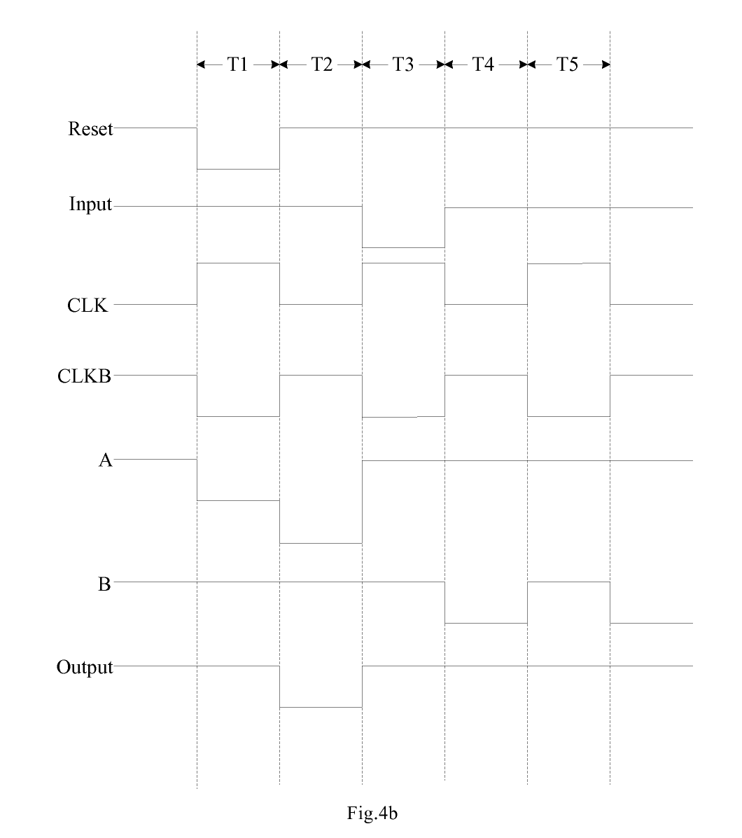

For example, the operation of the above shift register provided by an embodiment of the present disclosure can have five phases, as shown in FIG. 3a to FIG. 4b, which respectively are a first phase T1, a second phase T2, a third phase T3, a fourth phase T4, and a fifth phase T5.

1. The voltage of the DC voltage source VG is a low level voltage, the first reference voltage VDD is a high level voltage, the second reference voltage VSS is a low level voltage, and the input and output time sequence diagram during forward scan of the shift register is as shown in FIG. 3a.

At the first phase T1, the input signal Input and the second clock signal CLKB are at high levels, the input module 1 provides the first reference voltage VDD to the first node A under the control of the input signal Input, and the voltage of the first node A is the first voltage that is the high level voltage; the first output module 3 provides the first clock signal CLK of low level to the signal output terminal Output under the control of the first node A, and the second output module 4 provides the voltage of the DC voltage source of low level to the second node B and the signal output terminal Output under the control of the second clock signal CLKB; the second control sub-module 52 causes the voltage of the second node B to be the second voltage that is the low level voltage under the control of the first node A; therefore, at this phase, the voltage of the first node A is the high level voltage, the voltage of the second node B is the low level voltage, and the signal output terminal Output outputs the low level signal.

At the second phase T2, the first clock signal CLK is at the high level, the voltage of the first node A is still the first voltage, the first output module 3 provides the first clock signal CLK to the signal output terminal Output, and the third control sub-module 53 provides the first clock signal CLK to the second node B under the control of the first clock signal CLK and the second control sub-module 52 causes the voltage of the second node B to be the second voltage that is the low level voltage when the voltage of the first node A is the first voltage; therefore, at this phase, the voltage of the first node A is the high level voltage, the voltage of the second node B is the low level voltage, and the signal output terminal Output outputs the high level signal.

At the third phase T3, the reset signal Reset and the second clock signal CLKB are at high levels, the reset module 2 provides the second reference voltage VSS to the first node A under the control of the reset signal Reset; the second output module 4 provides the voltage of the DC voltage source VG to the second node B and the signal output terminal Output under the control of the second clock signal CLKB; therefore, at this phase, the voltage of the first node A is the low level voltage, the voltage of the second node B is the low level voltage, and the signal output terminal Output outputs the low level signal.

At the fourth phase T4, the first clock signal CLK is at the high level, the third control sub-module 53 provides the first clock signal CLK to the second node B under the control of the first clock signal CLK, the voltage of the second node B is the first voltage, and the first control sub-module 51 causes the voltage of the first node A to be the second voltage when the voltage of the second node B is the first voltage; the second output module 4 provides the voltage of the DC voltage source VG to the signal output terminal Output under the control of the second node B; therefore, at this phase, the voltage of the first node A is the low level voltage, the voltage of the second node B is the high level voltage, and the signal output terminal Output outputs the low level signal.

At the fifth phase T5, the second clock signal CLKB is at the high level, the second output module 4 provides the voltage of the DC voltage source VG to the second node B and the signal output terminal Output under the control of the second clock signal CLKB; therefore, at this phase, the voltage of the first node A is the low level voltage, the voltage of the second node B is the low level voltage, and the signal output terminal Output outputs the low level signal.

2. The voltage of the DC voltage source is a low level voltage, the first reference voltage VDD is a low level voltage, the second reference voltage VSS is a high level voltage, and the input and output time sequence diagram during reverse scan of the shift register is as shown in FIG. 3b.

At the first phase T1, the reset signal Reset and the second clock signal CLKB are at high levels, the reset module 2 provides the second reference voltage VSS to the first node A under the control of the reset signal Reset, and the voltage of the first node A is the first voltage that is the high level voltage; the first output module 3 provides the first clock signal CLK of low level to the signal output terminal Output under the control of the first node A, and the second output module 4 provides the voltage of the DC voltage source VG of low level to the second node B and the signal output terminal Output under the control of the second clock signal CLKB; the second control sub-module 52 causes the voltage of the second node B to be the second voltage that is the low level voltage under the control of the first node A; therefore, at this phase, the voltage of the first node A is the high level voltage, the voltage of the second node B is the low level voltage, and the signal output terminal Output outputs the low level signal.

At the second phase T2, the first clock signal CLK is at the high level, the voltage of the first node A is still the first voltage, the first output module 3 provides the first clock signal CLK to the signal output terminal Output, the third control sub-module 53 provides the first clock signal CLK to the second node B under the control of the first clock signal CLK, and the second control sub-module 52 causes the voltage of the second node B to be the second voltage that is the low level voltage when the voltage of the first node A is the first voltage; therefore, at this phase, the voltage of the first node A is the high level voltage, the voltage of the second node B is the low level voltage, and the signal output terminal Output outputs the high level signal.

At the third phase T3, the input signal Input and the second clock signal CLKB are at high levels, the input module 1 provides the first reference voltage VDD to the first node A under the control of the input signal Input; the second output module 4 provides the voltage of the DC voltage source VG to the second node B and the signal output terminal Output under the control of the second clock signal CLKB; therefore, at this phase, the voltage of the first node A is the low level voltage, the voltage of the second node B is the low level voltage, and the signal output terminal Output outputs the low level signal.

At the fourth phase T4, the first clock signal CLK is at the high level, the third control sub-module 53 provides the first clock signal CLK to the second node B under the control of the first clock signal CLK, the voltage of the second node B is the first voltage, and the first control sub-module 51 causes the voltage of the first node A to be the second voltage when the voltage of the second node B is the first voltage; the second output module 4 provides the voltage of the DC voltage source VG to the signal output terminal Output under the control of the second node B; therefore, at this phase, the voltage of the first node A is the low level voltage, the voltage of the second node B is the high level voltage, and the signal output terminal Output outputs the low level signal.

At the fifth phase T5, the second clock signal CLKB is at the high level, the second output module 4 provides the voltage of the DC voltage source VG to the second node B and the signal output terminal Output under the control of the second clock signal CLKB; therefore, at this phase, the voltage of the first node A is the low level voltage, the voltage of the second node B is the low level voltage, and the signal output terminal Output outputs the low level signal.

3. The voltage of the DC voltage source VG is a high level voltage, the first reference voltage VDD is a low level voltage, the second reference voltage VSS is a high level voltage, and the input and output time sequence diagram during forward scan of the shift register is as shown in FIG. 4a.

At the first phase T1, the input signal Input and the second clock signal CLKB are at low levels, the input module 1 provides the first reference voltage VDD to the first node A under the control of the input signal Input, and the voltage of the first node A is the first voltage that is the low level voltage; the first output module 3 provides the first clock signal CLK of high level to the signal output terminal Output under the control of the first node A, and the second output module 4 provides the voltage of the DC voltage source VG of high level to the second node B and the signal output terminal Output under the control of the second clock signal CLKB; the second control sub-module 52 causes the voltage of the second node B to be the second voltage that is the high level voltage under the control of the first node A; therefore, at this phase, the voltage of the first node A is the low level voltage, the voltage of the second node B is the high level voltage, and the signal output terminal Output outputs the high level signal.

At the second phase T2, the first clock signal CLK is at the low level, the voltage of the first node A is still the first voltage, the first output module 3 provides the first clock signal CLK to the signal output terminal Output, and the third control sub-module 53 provides the first clock signal CLK to the second node B under the control of the first clock signal CLK and the second control sub-module 52 causes the voltage of the second node B to be the second voltage that is the high level voltage when the voltage of the first node A is the first voltage; therefore, at this phase, the voltage of the first node A is the low level voltage, the voltage of the second node B is the high level voltage, and the signal output terminal Output outputs the low level signal.

At the third phase T3, the reset signal Reset and the second clock signal CLKB are at low levels, the reset module 2 provides the second reference voltage VSS to the first node A under the control of the reset signal Reset; the second output module 4 provides the voltage of the DC voltage source VG to the second node B and the signal output terminal Output under the control of the second clock signal CLKB; therefore, at this phase, the voltage of the first node A is the high level voltage, the voltage of the second node B is the high level voltage, and the signal output terminal Output outputs the high level signal.

At the fourth phase T4, the first clock signal CLK is at the low level, the third control sub-module 53 provides the first clock signal CLK to the second node B under the control of the first clock signal CLK, the voltage of the second node B is the first voltage, and the first control sub-module 51 causes the voltage of the first node A to be the second voltage when the voltage of the second node B is the first voltage; the second output module 4 provides the voltage of the DC voltage source VG to the signal output terminal Output under the control of the second node B; therefore, at this phase, the voltage of the first node A is the high level voltage, the voltage of the second node B is the low level voltage, and the signal output terminal Output outputs the high level signal.

At the fifth phase T5, the second clock signal CLKB is at the low level, the second output module 4 provides the voltage of the DC voltage source VG to the second node B and the signal output terminal Output under the control of the second clock signal CLKB; therefore, at this phase, the voltage of the first node A is the high level voltage, the voltage of the second node B is the high level voltage, and the signal output terminal Output outputs the high level signal.

4. The voltage of the DC voltage source VG is a high level voltage, the first reference voltage VDD is a high level voltage, the second reference voltage VSS is a low level voltage, and the input and output time sequence diagram during reverse scan of the shift register is as shown in FIG. 4b.

At the first phase T1, the reset signal Reset and the second clock signal CLKB are at low levels, the reset module 2 provides the second reference voltage VSS to the first node A under the control of the reset signal Reset, and the voltage of the first node A is the first voltage that is the low level voltage; the first output module 3 provides the first clock signal CLK of high level to the signal output terminal Output under the control of the first node A, and the second output module 4 provides the voltage of the DC voltage source VG of high level to the second node B and the signal output terminal Output under the control of the second clock signal CLKB; the second control sub-module 52 causes the voltage of the second node B to be the second voltage that is the high level voltage under the control of the first node A; therefore, at this phase, the voltage of the first node A is the low level voltage, the voltage of the second node B is the high level voltage, and the signal output terminal Output outputs the high level signal.

At the second phase T2, the first clock signal CLK is at the low level, the voltage of the first node A is still the first voltage, the first output module 3 provides the first clock signal CLK to the signal output terminal Output, the third control sub-module 53 provides the first clock signal CLK to the second node B under the control of the first clock signal CLK, and the second control sub-module 52 causes the voltage of the second node B to be the second voltage that is the high level voltage when the voltage of the first node A is the first voltage; therefore, at this phase, the voltage of the first node A is the low level voltage, the voltage of the second node B is the high level voltage, and the signal output terminal Output outputs the low level signal.

At the third phase T3, the input signal Input and the second clock signal CLKB are at low levels, the input module 1 provides the first reference voltage VDD to the first node A under the control of the input signal Input; the second output module 4 provides the voltage of the DC voltage source VG to the second node B and the signal output terminal Output under the control of the second clock signal CLKB; therefore, at this phase, the voltage of the first node A is the high level voltage, the voltage of the second node B is the high level voltage, and the signal output terminal Output outputs the high level signal.

At the fourth phase T4, the first clock signal CLK is at the low level, the third control sub-module 53 provides the first clock signal CLK to the second node B under the control of the first clock signal CLK, the voltage of the second node B is the first voltage, and the first control sub-module 51 causes the voltage of the first node A to be the second voltage when the voltage of the second node B is the first voltage; the second output module 4 provides the voltage of the DC voltage source VG to the signal output terminal Output under the control of the second node B; therefore, at this phase, the voltage of the first node A is the high level voltage, the voltage of the second node B is the low level voltage, and the signal output terminal Output outputs the high level signal.

At the fifth phase T5, the second clock signal CLKB is at the low level, the second output module 4 provides the voltage of the DC voltage source VG to the second node B and the signal output terminal Output under the control of the second clock signal CLKB; therefore, at this phase, the voltage of the first node A is the high level voltage, the voltage of the second node B is the high level voltage, and the signal output terminal Output outputs the high level signal.

In the following, detailed description will be made on the present disclosure in connection with specific embodiments. It is noted that the embodiments are only for better explaining the present disclosure but not limiting the present disclosure.

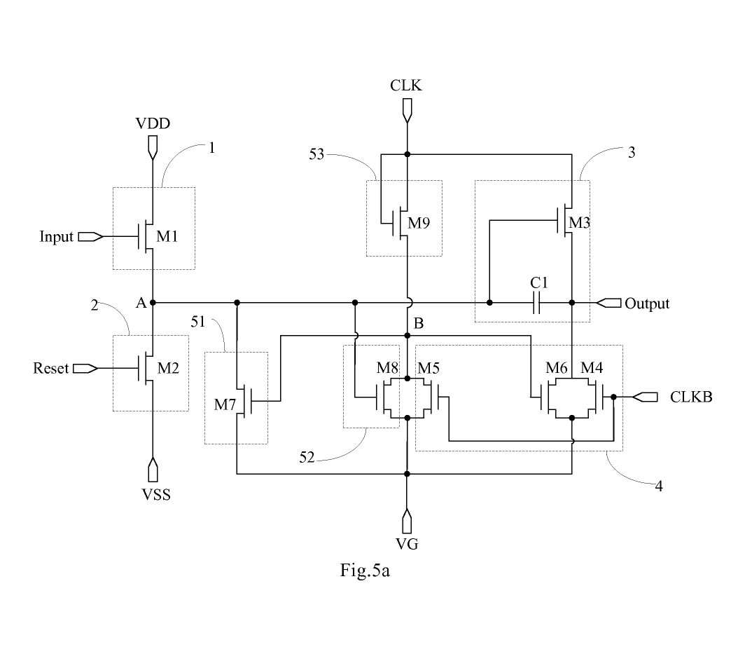

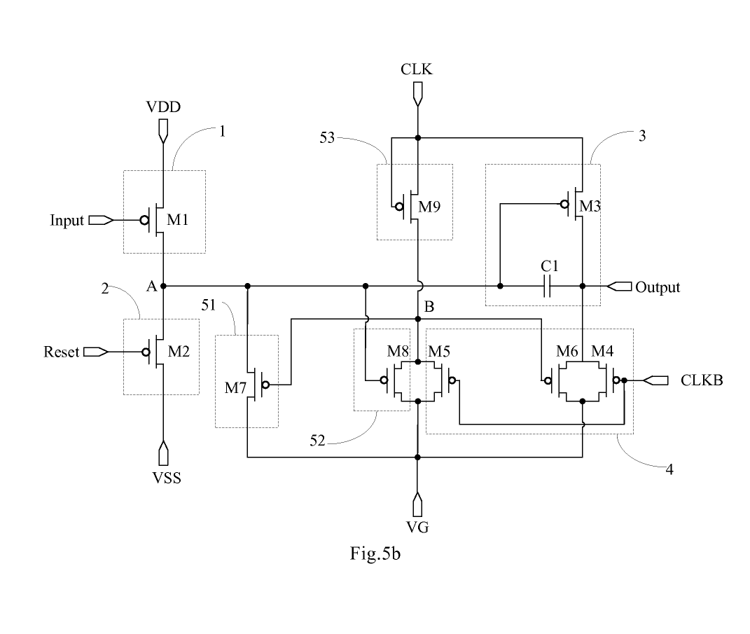

For example, in specific implementations, in the above shift register provided by embodiments of the present disclosure, as shown in FIG. 5a and FIG. 5b, the input module 1 can comprise a first switch transistor M1;

a gate of the first switch transistor M1 is connected with the input signal Input, a source of the first switch transistor M1 is connected with the first reference voltage VDD, and a drain of the first switch transistor M1 is connected to the first node A.

Further, in specific implementations, as shown in FIG. 5a, the first switch transistor M1 can be an N type transistor. In this case, when the input signal Input is at a high level, the first switch transistor M1 is turned on, and when the input signal Input is at a low level, the first switch transistor M1 is turned off. Alternatively, as shown in FIG. 5b, the first transistor M1 can also be a P type transistor. In this case, when the input signal Input is at a low level, the first switch transistor M1 is turned on, and when the input signal Input is at a high level, the first switch transistor M1 is turned off. They are not limited herein.

The above only exemplarily explains a specific structure of the input module in the shift register. In specific implementations, the specific structure of the input module is not limited to the above structure provided by an embodiment of the present disclosure, but can be other structures known by those skilled in the art. It is not limited herein.

For example, in specific implementations, in the above shift register provided by an embodiment of the present disclosure, as shown in FIG. 5a and FIG. 5b, the reset module 2 can comprise a second switch transistor M2;

a gate of the second switch transistor M2 is connected with the reset signal Reset, a source of the second switch transistor M2 is connected with the second reference voltage VSS, and a drain of the second switch transistor M2 is connected to the first node A.

Further, in specific implementations, as shown in FIG. 5a, the second switch transistor M2 can be an N type transistor. In this case, when the reset signal Reset is at a high level, the second switch transistor M2 is turned on, and when the reset signal Reset is at a low level, the second switch transistor M2 is turned off. Alternatively, as shown in FIG. 5b, the second switch transistor M2 can be a P type transistor. In this case, when the reset signal Reset is a the low level, the second switch transistor M2 is turned on, and when the reset signal Reset is at a high level, the second switch transistor M2 is turned off They are not limited herein.

The above only exemplarily explains a specific structure of the reset module in the shift register. In specific implementations, the specific structure of the reset module is not limited to the above structure provided by an embodiment of the present disclosure, but can be other structures known by those skilled in the art. It is not limited herein.

For example, in specific implementations, in the above shift register provided by an embodiment of the present disclosure, as shown in FIG. 5a and FIG. 5b, the first output module 3 can comprise a third switch transistor M3 and a capacitor C1, wherein

a gate of the third switch transistor M3 is connected to the first node A, a source of the third switch transistor M3 is connected with the first clock signal CLK, and a drain of the third switch transistor M3 is connected to the signal output terminal Output, and

the capacitor C1 is connected between the gate and the drain of the third switch transistor M3.

The capacitor C1 is arranged to, with the bootstrap effect of the capacitor C1, pull up during the time period T2 as shown in FIG. 3a and FIG. 3b or pull down during the time period T2 as shown in FIG. 4a and FIG. 4b the voltage of the first node A to keep the third switch transistor M3 in the turn-on state.

Further, in specific implementations, as shown in FIG. 5a, the third switch transistor M3 can be an N type transistor. In this case, when the voltage of the first node A is at a high level, the third switch transistor M3 is turned on, and when the voltage of the first node A is at a low level, the third switch transistor M3 is turned off. Alternatively, as shown in FIG. 5b, the third switch transistor M3 can be a P type transistor. In this case, when the voltage of the first node A is at a low level, the third switch transistor M3 is turned on, and when the voltage of the first node A is at a high level, the third switch transistor M3 is turned off. They are not limited herein.

The above only exemplarily explains a specific structure of the first output module in the shift register. In specific implementations, the specific structure of the first output module is not limited to the above structure provided by an embodiment of the present disclosure, but can be other structures known by those skilled in the art. It is not limited herein.

For example, in specific implementations, in the above shift register provided by an embodiment of the present disclosure, as shown in FIG. 5a and FIG. 5b, the second output module 4 can comprise a fourth switch transistor M4, a fifth switch transistor M5 and a sixth switch transistor M6, wherein

a gate of the fourth switch transistor M4 is connected with the second clock signal CLKB, a source of the fourth transistor M4 is connected to the DC voltage source VG, and a drain of the fourth switch transistor M4 is connected to the signal output terminal Output;

a gate of the fifth switch transistor M5 is connected with the second clock signal CLKB, a source of the fifth switch transistor M5 is connected to the DC voltage source VG, and a drain of the fifth switch transistor M5 is connected to the second node B;

a gate of the sixth switch transistor M6 is connected to the second node B, a source of the sixth switch transistor M6 is connected to the DC voltage source VG, a drain of the sixth switch transistor M6 is connected to the signal output terminal Output.

Further, in specific implementations, as shown in FIG. 5a, the fourth switch transistor M4 and the fifth switch transistor M5 can be N type transistors. In this case, when the second clock signal CLKB is at a high level, the fourth switch transistor M4 and the fifth switch transistor M5 are both turned on, and when the second clock signal CLKB is at a low level, the fourth switch transistor M4 and the fifth switch transistor M5 are both turned off. Alternatively, as shown in FIG. 5b, the fourth switch transistor M4 and the fifth switch transistor M5 can also be P type transistors. In this case, when the second clock signal CLKB is at a low level, the fourth switch transistor M4 and the fifth switch transistor M5 are both turned on, and when the second clock signal CLKB is at a high level, the fourth switch transistor M4 and the fifth switch transistor M5 are both turned off. They are not limited herein.

Further, in specific implementations, as shown in FIG. 5a, the sixth switch transistor M6 can be an N type transistor. In this case, when the voltage of the second node B is at a high level, the sixth switch transistor M6 is turned on, and when the voltage of the second node B is at a low level, the sixth switch transistor M6 is turned off. Alternatively, as shown in FIG. 5b, the sixth switch transistor M6 can be a P type transistor. In this case, when the voltage of the second node B is at a low level, the sixth switch transistor M6 is turned on, and when the voltage of the second node B is at a high level, the sixth switch transistor M6 is turned off. They are not limited herein.

The above only exemplarily explains a specific structure of the second output module in the shift register. In specific implementations, the specific structure of the second output module is not limited to the above structure provided by an embodiment of the present disclosure, but can be other structures known by those skilled in the art. It is not limited herein.

For example, in specific implementations, in the above shift register provided by an embodiment of the present disclosure, as shown in FIG. 5a and FIG. 5b, the first control sub-module 51 can comprise a seventh switch transistor M7;

a gate of the seventh switch transistor M7 is connected to the second node B, a source of the seventh switch transistor M7 is connected to the DC voltage source VG, and a drain of the seventh switch transistor M7 is connected to the first node A.

Further, in specific implementations, as shown in FIG. 5a, the seventh switch transistor M7 can be an N type transistor. In this case, when the voltage of the second node B is at a high level, the seventh switch transistor M7 is turned on, and when the voltage of the second node B is at a low level, the seventh switch transistor M7 is turned off. Alternatively, as shown in FIG. 5b, the seventh switch transistor M7 can be a P type transistor. In this case, when the voltage of the second node B is at a low level, the seventh switch transistor M7 is turned on, and when the voltage of the second node B is at a high level, the seventh switch transistor M7 is turned off. They are not limited herein.

The above only exemplarily explains a specific structure of the first control sub-module in the shift register. In specific implementations, the specific structure of the first control sub-module is not limited to the above structure provided by an embodiment of the present disclosure, but can be other structures known by those skilled in the art. It is not limited herein.

For example, in the above shift register provided by an embodiment of the present disclosure, as shown in FIG. 5a and FIG. 5b, the second control sub-module 52 can comprise an eighth switch transistor M8;

a gate of the eighth switch transistor M8 is connected to the first node A, a source of the eighth switch transistor M8 is connected to the DC voltage source VG, a drain of the eighth switch transistor M8 is connected to the second node B.

Further, in specific implementations, as shown in FIG. 5a, the eighth switch transistor M8 can be an N type transistor. In this case, when the voltage of the first node A is at a high level, the eighth switch transistor M8 is turned on, and when the voltage of the first node A is at a low level, the eighth switch transistor M8 is turned off. Alternatively, as shown in FIG. 5b, the eighth switch transistor M8 can be a P type transistor. In this case, when the voltage of the first node A is at a low level, the eighth switch transistor M8 is turned on, and when the voltage of the first node A is at a high level, the eighth switch transistor M8 is turned off. They are not limited herein.

The above only exemplarily explains a specific structure of the second control sub-module in the shift register. In specific implementations, the specific structure of the second control sub-module is not limited to the above structure provided by an embodiment of the present disclosure, but can be other structures known by those skilled in the art. It is not limited herein.

For example, in the above shift register provided by an embodiment of the present disclosure, as shown in FIG. 5a and FIG. 5b, the third control sub-module 53 can comprise a ninth switch transistor M9;

both a gate and a source of the ninth transistor M9 are connected with the first clock signal CLK, a drain of the ninth transistor M9 is connected to the second node B.

Further, in specific implementations, as shown in FIG. 5a, the ninth switch transistor M9 can be an N type transistor. In this case, when the first clock signal CLK is at a high level, the ninth switch transistor M9 is turned on, and when the first clock signal CLK is at a low level, the ninth switch transistor M9 is turned off. Alternatively, as shown in FIG. 5b, the ninth switch transistor M9 can be a P type transistor. In this case, when the first clock signal CLK is at a low level, the ninth switch transistor M9 is turned on, and when the first clock signal CLK is at a high level, the ninth switch transistor M9 is turned off. They are not limited herein.

The above only exemplarily explains a specific structure of the third control sub-module in the shift register. In specific implementations, the specific structure of the third control sub-module is not limited to the above structure provided by an embodiment of the present disclosure, but can be other structures known by those skilled in the art. It is not limited herein.

For example, in the above shift register provided by an embodiment of the present disclosure, the switch transistors generally adopt transistors with same materials. In specific implementations, in order to simplify the fabrication process, all the switch transistors that are the above first to ninth transistors adopt P type transistors or N type transistors. When the above first to ninth transistors are all N type transistors, the voltage of the DC voltage source is the low level voltage, during forward scan, the first reference voltage is the high level voltage, and the second reference voltage is the low level voltage, and during reverse scan, the first reference voltage is the low level voltage, and the second reference voltage is the high level voltage. When the above first to ninth transistors are all P type transistors, the voltage of the DC voltage source is the high level voltage, during forward scan, the first reference voltage is the low level voltage, and the second reference voltage is the high level voltage, and during reverse scan, the first reference voltage is the high level voltage, and the second reference voltage is the low level voltage.

It is noted that the switch transistors mentioned in the above embodiments of the present disclosure can be TFTs, or can be metal oxide semiconductor (MOS) transistors, which is not limited herein. In specific implementations, the gates and drains of those switch transistors can be exchanged in function depending on different types of transistors and different input signals, which are not distinguished specifically herein.

In the following, by taking the shift registers shown in FIG. 5a and FIG. 5b respectively as examples, their operation processes will be described in detail. In the following description, “1” represents a high level signal, and “0” represents a low level signal.

### Instance 1

In the shift register shown in FIG. 5a, all transistors are N type transistors, and each N type transistor is turned on under the effect of high level and turned off under the effect of low level. The voltage of the DC voltage source VG is a low level voltage. During forward scan, the first reference voltage VDD is a high level voltage, the second reference voltage VSS is a low level voltage, and the corresponding input and output time sequence diagram is as shown in FIG. 3a. In particular, five phases of T1, T2, T3, T4 and T5 in the input and output time sequence diagram as shown in FIG. 3a are selected.

At phase T1, Input=1, CLKB=1, Reset=0, CLK=0. The first transistor M1 is turned on to provide the first reference voltage VDD to the first node A, and the voltage of the first node A is the high level voltage; the third switch transistor M3 and the eighth switch transistor M8 are turned on under the control of the first node A, the turned-on third switch transistor M3 provides the first clock signal CLK of low level to the signal output terminal Output, and the turned-on eighth switch transistor M8 provides the voltage of the DC voltage source VG of low level to the second node B. The capacitor is charged. In addition, under the control of the second clock signal CLKB, the fourth switch transistor M4 and the fifth switch transistor M5 are turned on, the turned-on fourth switch transistor M4 provides the voltage of the DC voltage source VG of low level to the signal output terminal Output, and the turned-on fifth switch transistor M5 provides the voltage of the DC voltage source VG of low level to the second node B. Therefore, at this phase, the voltage of the first node A is the high level voltage, the voltage of the second node B is the low level voltage, and the signal output terminal Output outputs the low level signal.

At phase T2, CLK=1, Input=0, CLKB=0, Reset=0. At the instant that the first clock signal CLK changes from the low level to the high level, the voltage of the first node A is still the high level at phase T1, and now the third switch transistor M3 is turned on to provide the first clock signal CLK of high level to the signal output terminal to cause the voltage of the signal output terminal to be the high level. Due to the bootstrap effect of capacitor C1, the voltage of one terminal of the capacitor C1 is raised, and the voltage of the other terminal (that is the first node A) of the capacitor C1 is further pulled up. Therefore, the eighth switch transistor M8 is turned on to provide the voltage of the DC voltage source VG of low level to the second node B. Although the ninth switch transistor M9 provides the first clock signal CLK to the second node B under the control of the first clock signal CLK, the voltage of the second node B is still the low level, and the first node A is always at the high level due to the bootstrap effect of the capacitor C1; therefore, the third switch transistor M3 is turned on to provide the first clock signal CLK of high level to the signal output terminal Output. Therefore, at this phase, the voltage of the first node A is the high level voltage, the voltage of the second node B is the low level voltage, and the signal output terminal Output outputs the high level signal.

At phase T3, Reset=1, CLKB=1, Input=0, CLK=0. The second switch transistor M2, the fourth switch transistor M4 and the fifth switch transistor M5 are turned on. The turned-on second switch transistor M2 provide the second reference voltage VSS of low level to the first node A, the turned-on fourth switch transistor M4 provides the voltage of the DC voltage source VG of low level to the signal output terminal Output, and the turned-on fifth switch transistor M5 provides the voltage of the DC voltage source VG of low level to the second node B. Therefore, at this phase, the voltage of the first node A is the low level voltage, the voltage of the second node B is the low level voltage, and the signal output terminal Output outputs the low level signal.

At phase T4, CLK=1, Reset=0, CLKB=0, Input=0. The ninth switch transistor M9 is turned on to provide the first clock signal CLK of high level to the second node B. Under the control of the second node B, the sixth switch transistor M6 and the seventh switch transistor M7 are turned on. The turned-on seventh switch transistor M7 provides the voltage of the DC voltage source VG of low level to the first node A, and the turned-on sixth switch transistor M6 provides the voltage of the DC voltage source VG of low level to the signal output terminal Output. Therefore, at this phase, the voltage of the first node A is the low level voltage, the voltage of the second node B is the high level voltage, and the signal output terminal Output outputs the low level signal.

At phase T5, CLKB=1, Reset=0, Input=0, CLK=0. The fourth switch transistor M4 and the fifth switch transistor M5 are turned on. The turned-on switch transistor M5 provides the voltage of the DC voltage source VG to the second node B, and the turned-on fourth switch transistor M4 provides the voltage of the DC voltage source VG to the signal output terminal Output. Therefore, at this phase, the voltage of the first node A is the low level voltage, the voltage of the second node B is the low level voltage, and the signal output terminal Output outputs the low level signal.

Then, phases T4 and T5 are repeated, the voltage of the first node A is always the low level voltage, and the voltage of the second node B is alternately high and low level voltages, such that the life span of the above shift register is ensured. In addition, the signal output terminal Output always outputs the low level signal, such that noises of signals output by the signal output terminal Output of the above shift register are reduced. Further, the number of switch transistors used by the above shift register is small, such that space can be saved to realize a narrow frame.

### Instance 2

In the shift register shown in FIG. 5a, all transistors are N type transistors, and each N type transistor is turned on under the effect of high level and turned off under the effect of low level. The voltage of the DC voltage source VG is a low level voltage. During reverse scan, the input signal Input is taken as the reset signal Reset, and the reset signal Reset is taken as the input signal Input. The first reference voltage VDD is a low level voltage, the second reference voltage VDD is a high level voltage, and the corresponding input and output time sequence diagram is as shown in FIG. 3b. In particular, five phases of T1, T2, T3, T4 and T5 in the input and output time sequence diagram as shown in FIG. 3b are selected.

At phase T1, Reset=1, CLKB=1, Input=0, CLK=0. The second switch transistor M2 is turned on to provide the second reference voltage VSS to the first node A, and the voltage of the first node A is the high level voltage. Under the control of the first node A, the third switch transistor M3 and the eighth switch transistor M8 are turned on. The turned-on third switch transistor M3 provides the first clock signal CLK of low level to the signal output terminal Output, and the turned-on eighth switch transistor M8 provides the voltage of the DC voltage source VG of low level to the second node B. The capacitor C1 is charged. In addition, under the control of the second clock signal CLKB, the fourth switch transistor M4 and the fifth switch transistor M5 are turned on. The turned-on fourth switch transistor M4 provides the voltage of the DC voltage source VG of low level to the signal output terminal Output, and the turned-on fifth switch transistor M5 provides the voltage of the DC voltage source VG of low level to the second node B. Therefore, at this phase, the voltage of the first node A is the high level voltage, the voltage of the second node B is the low level voltage, and the signal output terminal Output outputs the low level signal.

At phase T2, CLK=1, Input=0, CLKB=0, Reset=0. At the instant that the first clock signal CLK changes from the low level to the high level, the voltage of the first node A is still the high level at phase T1, and now the third switch transistor M3 is turned on to provide the first clock signal CLK of high level to the signal output terminal to cause the voltage of the signal output terminal to be the high level. Due to the bootstrap effect of the capacitor C1, the voltage of one terminal of the capacitor C1 is raised, and the voltage of the other terminal (that is the first node A) of the capacitor C1 is further pulled up. Therefore, the eighth switch transistor M8 is turned on to provide the voltage of the DC voltage source VG of low level to the second node B. Although the ninth switch transistor M9 provides the first clock signal CLK to the second node B under the control of the first clock signal CLK, the voltage of the second node B is still the low level, and the first node A is always at the high level due to the bootstrap effect of the capacitor C1; therefore, the third switch transistor M3 is turned on to provide the first clock signal CLK of high level to the signal output terminal Output. Therefore, at this phase, the voltage of the first node A is the high level voltage, the voltage of the second node B is the low level voltage, and the signal output terminal Output outputs the high level signal.

At phase T3, Input=1, CLKB=1, Reset=0, CLK=0. The first switch transistor M1, the fourth switch transistor M4 and the fifth switch transistor M5 are turned on. The turned-on first switch transistor M1 provides the first reference voltage VDD of low level to the first node A, the turned-on fourth switch transistor M4 provides the voltage of the DC voltage source VG of low level to the signal output terminal Output, and the turned-on fifth switch transistor M5 provides the voltage of the DC voltage source VG of low level to the second node B. Therefore, at this phase, the voltage of the first node A is the low level voltage, the voltage of the second node B is the low level voltage, and the signal output terminal Output outputs the low level signal.

At phase T4, CLK=1, Reset=0, CLKB=0, Input=0. The ninth switch transistor M9 is turned on to provide the first clock signal CLK of high level to the second node B. Under the control of the second node B, the sixth switch transistor M6 and the seventh switch transistor M7 are turned on. The turned-on seventh switch transistor M7 provides the voltage of the DC voltage source VG of low level to the first node A, and the turned-on sixth switch transistor M6 provides the voltage of the DC voltage source VG of low level to the signal output terminal Output. Therefore, at this phase, the voltage of the first node A is the low level voltage, the voltage of the second node B is the high level voltage, and the signal output terminal Output outputs the low level signal.

At phase T5, CLKB=1, Reset=0, Input=0, CLK=0. The fourth switch transistor M4 and the fifth switch transistor M5 are turned on. The turned-on switch transistor M5 provides the voltage of the DC voltage source VG to the second node B, and the turned-on fourth switch transistor M4 provides the voltage of the DC voltage source VG to the signal output terminal Output. Therefore, at this phase, the voltage of the first node A is the low level voltage, the voltage of the second node B is the low level voltage, and the signal output terminal Output outputs the low level signal.

Then, phases T4 and T5 are repeated, the voltage of the first node A is always the low level voltage, and the voltage of the second node B is alternately high and low level voltages, such that the life span of the above shift register is ensured. In addition, the signal output terminal Output always outputs the low level signal, such that noises of signals output by the signal output terminal Output of the above shift register are reduced. Further, the number of switch transistors used by the above shift register is small, such that space can be saved to realize a narrow frame.

### Instance 3

In the shift register shown in FIG. 5b, all transistors are P type transistors, and each P type transistor is turned on under the effect of low level and turned off under the effect of high level. The voltage of the DC voltage source VG is a high level voltage. During forward scan, the first reference voltage VDD is a low level voltage, the second reference voltage VSS is a high level voltage, and the corresponding input and output time sequence diagram is as shown in FIG. 4a. In particular, five phases of T1, T2, T3, T4 and T5 in the input and output time sequence diagram as shown in FIG. 4a are selected.

At phase T1, Input=0, CLKB=0, Reset=1, CLK=1. The first transistor M1 is turned on to provide the first reference voltage VDD to the first node A, and the voltage of the first node A is the low level voltage; the third switch transistor M3 and the eighth switch transistor M8 are turned on under the control of the first node A, the turned-on third switch transistor M3 provides the first clock signal CLK of high level to the signal output terminal Output, and the turned-on eighth switch transistor M8 provides the voltage of the DC voltage source VG of high level to the second node B. The capacitor C1 is charged. In addition, under the control of the second clock signal CLKB, the fourth switch transistor M4 and the fifth switch transistor M5 are turned on, the turned-on fourth switch transistor M4 provides the voltage of the DC voltage source VG of high level to the signal output terminal Output, and the turned-on fifth switch transistor M5 provides the voltage of the DC voltage source VG of high level to the second node B. Therefore, at this phase, the voltage of the first node A is the low level voltage, the voltage of the second node B is the high level voltage, and the signal output terminal Output outputs the high level signal.

At phase T2, CLK=0, Input1, CLKB=1, Reset=1. At the instant that the first clock signal CLK changes from the high level to the low level, the voltage of the first node A is still the low level at phase T1, and now the third switch transistor M3 is turned on to provide the first clock signal CLK of low level to the signal output terminal to cause the voltage of the signal output terminal to be the low level. Due to the bootstrap effect of the capacitor C1, the voltage of one terminal of the capacitor C1 is reduced, and the voltage of the other terminal (that is the first node A) of the capacitor C1 is further pulled down. Therefore, the eighth switch transistor M8 is turned on to provide the voltage of the DC voltage source VG of high level to the second node B. Although the ninth switch transistor M9 provides the first clock signal CLK to the second node B under the control of the first clock signal CLK, the voltage of the second node B is still the high level, and the first node A is always at the low level due to the bootstrap effect of the capacitor C1; therefore, the third switch transistor M3 is turned on to provide the first clock signal CLK of low level to the signal output terminal Output. Therefore, at this phase, the voltage of the first node A is the low level voltage, the voltage of the second node B is the high level voltage, and the signal output terminal Output outputs the low level signal.

At phase T3, Reset=0, CLKB=0, Input=1, CLK=1. The second switch transistor M2, the fourth switch transistor M4 and the fifth switch transistor M5 are turned on. The turned-on second switch transistor M2 provide the second reference voltage VSS of high level to the first node A, the turned-on fourth switch transistor M4 provides the voltage of the DC voltage source VG of high level to the signal output terminal Output, and the turned-on fifth switch transistor M5 provides the voltage of the DC voltage source VG of high level to the second node B. Therefore, at this phase, the voltage of the first node A is the high level voltage, the voltage of the second node B is the high level voltage, and the signal output terminal Output outputs the high level signal.

At phase T4, CLK=0, Reset=1, CLKB=1, Input=1. The ninth switch transistor M9 is turned on to provide the first clock signal CLK of low level to the second node B. Under the control of the second node B, the sixth switch transistor M6 and the seventh switch transistor M7 are turned on. The turned-on seventh switch transistor M7 provides the voltage of the DC voltage source VG of high level to the first node A, and the turned-on sixth switch transistor M6 provides the voltage of the DC voltage source VG of high level to the signal output terminal Output. Therefore, at this phase, the voltage of the first node A is the high level voltage, the voltage of the second node B is the low level voltage, and the signal output terminal Output outputs the high level signal.

At phase T5, CLKB=0, Reset=1, Input=1, CLK=1. The fourth switch transistor M4 and the fifth switch transistor M5 are turned on. The turned-on switch transistor M5 provides the voltage of the DC voltage source VG to the second node B, and the turned-on fourth switch transistor M4 provides the voltage of the DC voltage source VG to the signal output terminal Output. Therefore, at this phase, the voltage of the first node A is the high level voltage, the voltage of the second node B is the high level voltage, and the signal output terminal Output outputs the high level signal.

Then, phases T4 and T5 are repeated, the voltage of the first node A is always the high level voltage, and the voltage of the second node B is alternately high and low level voltages, such that the life span of the above shift register is ensured. In addition, the signal output terminal Output always outputs the high level signal, such that noises of signals output by the signal output terminal Output of the above shift register are reduced. Further, the number of switch transistors used by the above shift register is small, such that space can be saved to realize a narrow frame.

### Instance 4

In the shift register shown in FIG. 5b, all transistors are P type transistors, and each P type transistor is turned on under the effect of low level and turned off under the effect of high level. The voltage of the DC voltage source VG is a high level voltage. During reverse scan, the input signal Input is taken as the reset signal Reset, and the reset signal Reset is taken as the input signal Input. The first reference voltage VDD is a high level voltage, the second reference voltage VSS is a low level voltage, and the corresponding input and output time sequence diagram is as shown in FIG. 4b. In particular, five phases of T1, T2, T3, T4 and T5 in the input and output time sequence diagram as shown in FIG. 4b are selected.

At phase T1, Reset=0, CLKB=0, Input=1, CLK=1. The second switch transistor M2 is turned on to provide the second reference voltage VSS to the first node A, and the voltage of the first node A is the low level voltage. Under the control of the first node A, the third switch transistor M3 and the eighth switch transistor M8 are turned on. The turned-on third switch transistor M3 provides the first clock signal CLK of high level to the signal output terminal Output, and the turned-on eighth switch transistor M8 provides the voltage of the DC voltage source VG of high level to the second node B. The capacitor C1 is charged. In addition, under the control of the second clock signal CLKB, the fourth switch transistor M4 and the fifth switch transistor M5 are turned on. The turned-on fourth switch transistor M4 provides the voltage of the DC voltage source of high level to the signal output terminal Output, and the turned-on fifth switch transistor M5 provides the voltage of the DC voltage source VG of high level to the second node B. Therefore, at this phase, the voltage of the first node A is the low level voltage, the voltage of the second node B is the high level voltage, and the signal output terminal Output outputs the high level signal.

At phase T2, CLK=0, Input=1, CLKB=1, Reset=1. At the instant that the first clock signal CLK changes from the high level to the low level, the voltage of the first node A is still the low level at phase T1, and now the third switch transistor M3 is turned on to provide the first clock signal CLK of low level to the signal output terminal to cause the voltage of the signal output terminal to be the low level. Due to the bootstrap effect of the capacitor C1, the voltage of one terminal of the capacitor C1 is reduced, and the voltage of the other terminal (that is the first node A) of the capacitor C1 is further pulled down. Therefore, the eighth switch transistor M8 is turned on to provide the voltage of the DC voltage source VG of high level to the second node B. Although the ninth switch transistor M9 provides the first clock signal CLK to the second node B under the control of the first clock signal CLK, the voltage of the second node B is still the high level, and the first node A is always at the low level due to the bootstrap effect of the capacitor C1; therefore, the third switch transistor M3 is turned on to provide the first clock signal CLK of low level to the signal output terminal Output. Therefore, at this phase, the voltage of the first node A is the low level voltage, the voltage of the second node B is the high level voltage, and the signal output terminal Output outputs the low level signal.

At phase T3, Input=0, CLKB=0, Reset=1, CLK=1. The first switch transistor M1, the fourth switch transistor M4 and the fifth switch transistor M5 are turned on. The turned-on first switch transistor M1 provides the first reference voltage VDD of high level to the first node A, the turned-on fourth switch transistor M4 provides the voltage of the DC voltage source VG of high level to the signal output terminal Output, and the turned-on fifth switch transistor M5 provides the voltage of the DC voltage source VG of high level to the second node B. Therefore, at this phase, the voltage of the first node A is the high level voltage, the voltage of the second node B is the high level voltage, and the signal output terminal Output outputs the high level signal.

At phase T4, CLK=0, Reset=1, CLKB=1, Input=1. The ninth switch transistor M9 is turned on to provide the first clock signal CLK of low level to the second node B. Under the control of the second node B, the sixth switch transistor M6 and the seventh switch transistor M7 are turned on. The turned-on seventh switch transistor M7 provides the voltage of the DC voltage source VG of high level to the first node A, and the turned-on sixth switch transistor M6 provides the voltage of the DC voltage source VG of high level to the signal output terminal Output. Therefore, at this phase, the voltage of the first node A is the high level voltage, the voltage of the second node B is the low level voltage, and the signal output terminal Output outputs the high level signal.

At phase T5, CLKB=0, Reset=1, Input=1, CLK=1. The fourth switch transistor M4 and the fifth switch transistor M5 are turned on. The turned-on switch transistor M5 provides the voltage of the DC voltage source VG to the second node B, and the turned-on fourth switch transistor M4 provides the voltage of the DC voltage source VG to the signal output terminal Output. Therefore, at this phase, the voltage of the first node A is the high level voltage, the voltage of the second node B is the high level voltage, and the signal output terminal Output outputs the high level signal.

Then, phases T4 and T5 are repeated, the voltage of the first node A is always the high level voltage, and the voltage of the second node B is alternately high and low level voltages, such that the life span of the above shift register is ensured. In addition, the signal output terminal Output always outputs the high level signal, such that noises of signals output by the signal output terminal Output of the above shift register are reduced. Further, the number of switch transistors used by the above shift register is small, such that space can be saved to realize a narrow frame.

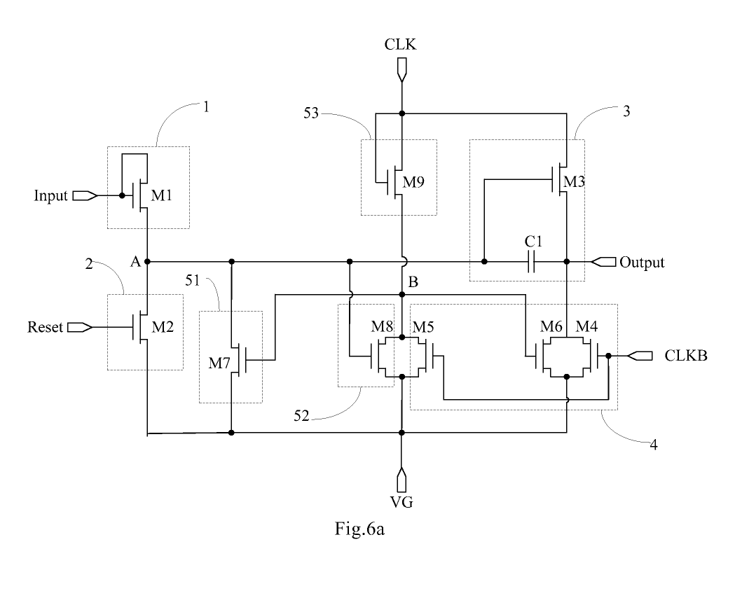

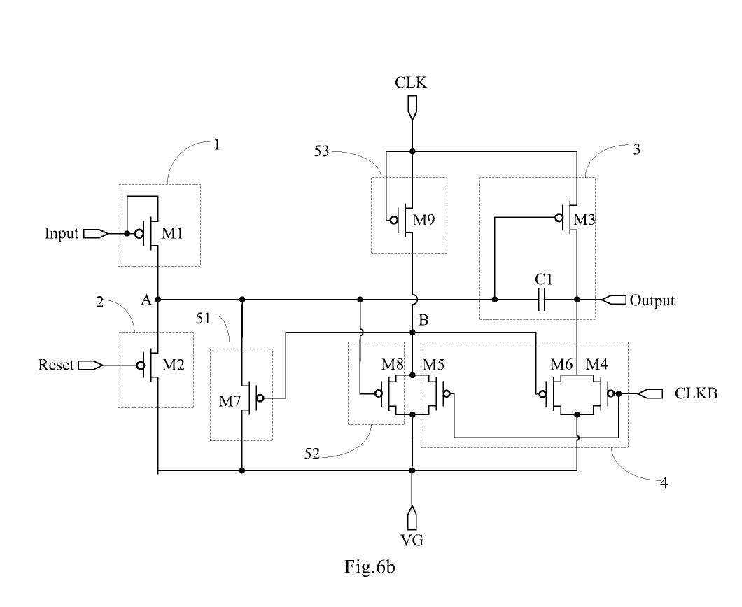

Further, in the above shift register provided by an embodiment of the present disclosure, when bi-directional scan is not considered but only unidirectional scan needs to be realized, as shown in FIG. 6a and FIG. 6b, the input signal Input is used to replace the first reference voltage VDD, and the DC voltage source VG is used to replace the second reference signal VSS, such as to realize forward scan. The principle of the forward scan is the same as the principle that the above shift register as shown in FIG. 5a and FIG. 5b uses to realize the forward scan, which will not be repeated here.

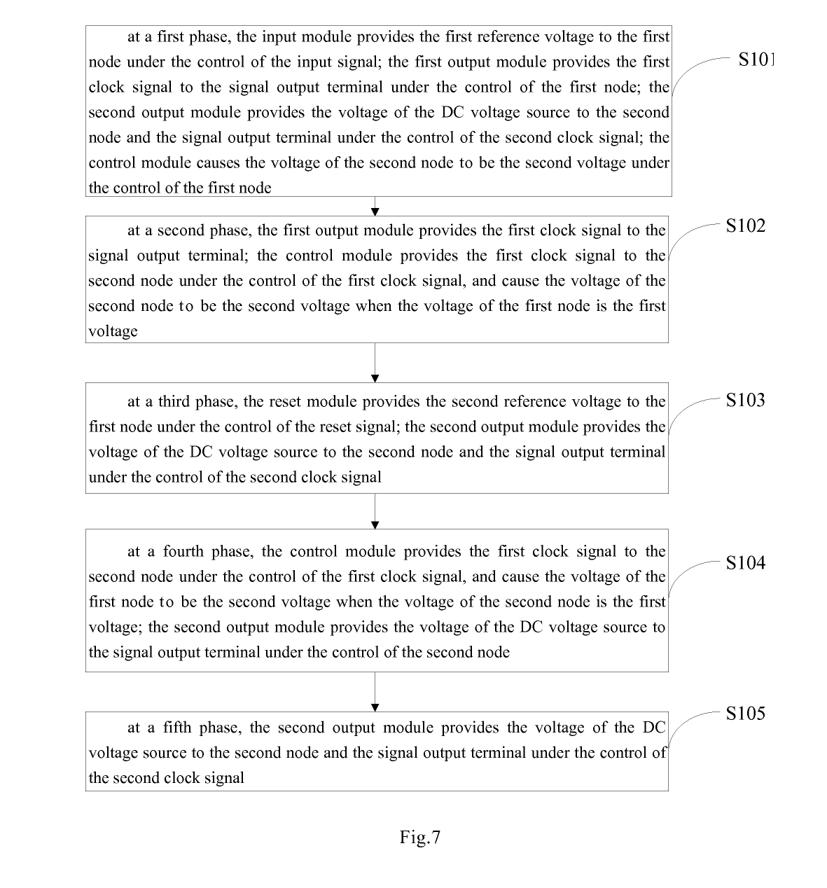

Based on the same inventive concept, an embodiment of the present disclosure also provides a driving method of any shift register as described in the above, as shown in FIG. 7, which can comprise the following steps.

In S101, at a first phase, the input module provides the first reference voltage to the first node under the control of the input signal; the first output module provides the first clock signal to the signal output terminal under the control of the first node; the second output module provides the voltage of the DC voltage source to the second node and the signal output terminal under the control of the second clock signal; the control module causes the voltage of the second node to be the second voltage under the control of the first node.

In S102, at a second phase, the first output module provides the first clock signal to the signal output terminal; the control module provides the first clock signal to the second node under the control of the first clock signal, and cause the voltage of the second node to be the second voltage when the voltage of the first node is the first voltage.

In S103, at a third phase, the reset module provides the second reference voltage to the first node under the control of the reset signal; the second output module provides the voltage of the DC voltage source to the second node B and the signal output terminal under the control of the second clock signal.

In S104, at a fourth phase, the control module provides the first clock signal to the second node under the control of the first clock signal, and cause the voltage of the first node to be the second voltage when the voltage of the second node is the first voltage; the second output module provides the voltage of the DC voltage source to the signal output terminal under the control of the second node.

In S105, at a fifth phase, the second output module provides the voltage of the DC voltage source to the second node and the signal output terminal under the control of the second clock signal.

The above driving method provided by an embodiment of the present disclosure causes the shift register to use the first clock signal to control the second node, and then control the signal output by the signal output terminal by alternate high/low levels of the second node and the second clock signal, such that the signal output terminal can always output signals to eliminate noises and stabilize row output signals. In addition, since the second node has alternate high/low levels, the life span of the shift register can be protected.

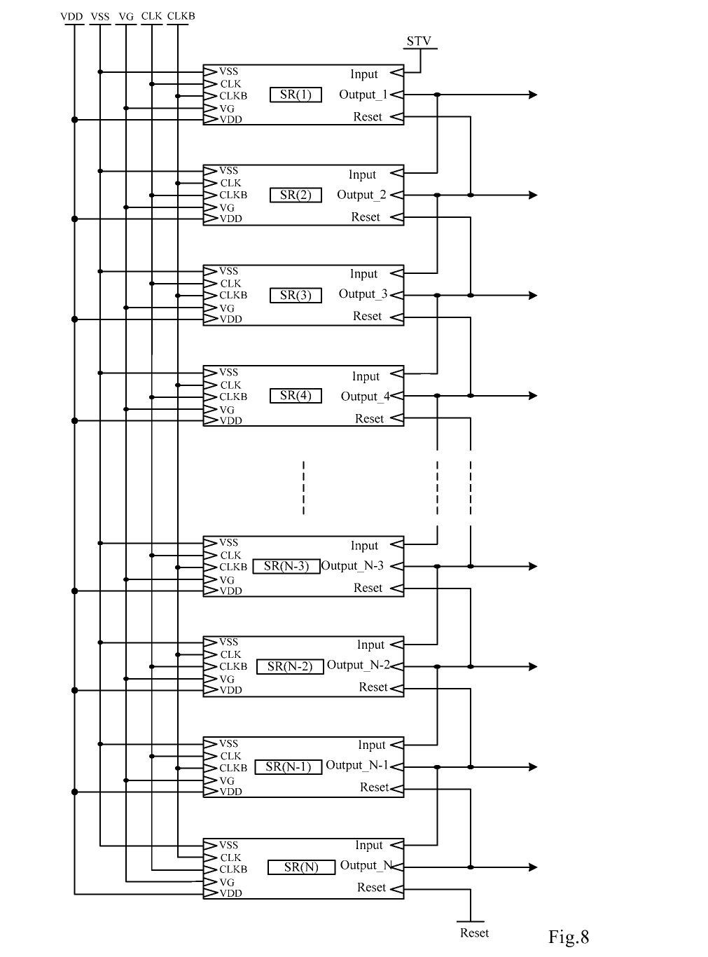

Based on the same inventive concept, an embodiment of the present disclosure also provides a gate driving circuit, as shown in FIG. 8, comprising multiple shift registers of any type described in the above which are connected in series: SR(1), SR(2) . . . SR(n) . . . SR(N−1), SR(N) (totally N shift registers, 1≦n≦N).

Except the first stage of shift register SR(1), the signal output terminal Output_n (1≦n≦N) of each stage of shift register SR(n) inputs a reset signal Reset to its adjacent previous stage of shift register SR(n−1).

Except the last stage of shift register SR(N), the signal output terminal Output_n (1≦n≦N) of each stage of shift register SR(n) inputs an input signal Input to its adjacent next stage of shift register SR(n+1).

The input signal Input of the first stage of shift register SR(1) is input by a frame start signal STV terminal.

Further, in the above gate driving circuit provided by an embodiment of the present disclosure, the first clock signal CLK, the second clock signal CLKB, the first reference voltage VDD, the second reference voltage VSS and the DC voltage source VG are all input into each stage of shift register.

In addition, as shown in FIG. 8, in the gate driving apparatus, clock signals input into first clock signal terminals of two adjacent stages of shift register have opposite phases to each other, and clock signals input into second clock signal terminals of two adjacent stages of shift register have opposite phases to each other. For example, the first clock signal terminal of the shift register SR(1) is input the CLK signal, and the second clock signal terminal of the shift register SR(1) is input the CLKB signal; the first clock signal terminal of the shift register SR(2) is input the CLKB signal, and the second clock signal terminal of the shift register SR(2) is input the CLK signal, wherein, the CLK signal and the CLKB signal have opposite phases.

The specific structure of each shift register in the above gate driving circuit is the same as the above shift register in the present disclosure in function and structure, which will not be repeated here.

Based on the same inventive concept, an embodiment of the present disclosure also provides a display apparatus comprising the above gate driving circuit which provides scan signals to gate lines on the array substrate in the display apparatus. The specific implementation of the display apparatus can refer to the description on the above gate driving circuit. The same points will not be repeated here.

Embodiments of the present disclosure provide a shift register, driving method thereof, a gate driving circuit and a display apparatus, wherein the shift register comprises an input module, a reset module, a first output module, a second output module and a control module. The input module is configured to provide a first reference voltage to a first node under the control of an input signal; the reset module is configured to provide a second reference voltage to the first node under the control of a reset signal; the first output module is configured to provide a first clock signal to a signal output terminal when the voltage of the first node is a first voltage; the second output module is configured to provide a voltage of a DC voltage source to a second node and the signal output terminal under the control of a second clock signal and provide the voltage of the DC voltage source to the signal output terminal when the voltage of the second node is the first voltage; the control module is configured to cause the voltage of the first node to be a second voltage when the voltage of the second node is the first voltage, cause the voltage of the second node to be the second voltage when the voltage of the first node is the first voltage, and provide the first clock signal to the second node under the control of the first clock signal. The shift register uses the first clock signal to control the second node, and controls the signal output by the signal output terminal by alternate high/low levels of the second node and the second clock signal, such that the signal output terminal can always output signals to eliminate noises and stabilize row output signals. In addition, since the second node has alternate high/low levels, the life span of the shift register can be protected.

Obviously, those skilled in the art can make various modifications and variations to the present disclosure without departing from the spirit and the scope of the present disclosure. As such, if those modifications and variations fall within the scope of the claims and their equivalent of the present disclosure, the present disclosure is intended to incorporate those modifications and variations.

What is claimed is:

1. A shift register comprising an input module, a reset module, a first output module, a second output module and a control module, wherein
the input module is configured to provide a first reference voltage to a first node under the control of an input signal; the first node is a connection point of the input module, the reset module, the first output module and the control module;
the reset module is configured to provide a second reference voltage to the first node under the control of a reset signal;
the first output module is configured to provide a first clock signal to a signal output terminal when the voltage of the first node is a first voltage;
the second output module is configured to provide a voltage of a DC voltage source to a second node and the signal output terminal under the control of a second clock signal and provide the voltage of the DC voltage source to the signal output terminal when the voltage of the second node is the first voltage; the second node is a connection point of the second output module and the control module;
the control module is configured to cause the voltage of the first node to be a second voltage when the voltage of the second node is the first voltage, cause the voltage of the second node to be the second voltage when the voltage of the first node is the first voltage, and provide the first clock signal to the second node under the control of the first clock signal;
the first clock signal has an opposite phase to the second clock signal;
the first voltage is a high level voltage, the second voltage is a low level voltage, and the voltage of the DC voltage source is a low level voltage; or the first voltage is a low level voltage, the second voltage is a high level voltage, and the voltage of the DC voltage source is a high level voltage.

2. The shift register according to claim 1, wherein the control module comprises: a first control sub-module, a second control sub-module and a third control sub-module;
the first control sub-module is configured to provide the voltage of the DC voltage source to the first node when the voltage of the second node is the first voltage;
the second control sub-module is configured to provide the voltage of the DC voltage source to the second node when the voltage of the first node is the first voltage;
the third control sub-module is configured to provide the first clock signal to the second node under the control of the first clock signal.

3. The shift register according to claim 2, wherein the input module comprises a first switch transistor;
a gate of the first switch transistor is connected with the input signal, a source of the first switch transistor is connected with the first reference voltage, and a drain of the first switch transistor is connected to the first node.

4. The shift register according to claim 3, wherein the reset module comprises a second switch transistor;
a gate of the second switch transistor is connected with the reset signal, a source of the second switch transistor is connected with the second reference voltage, and a drain of the second switch transistor is connected to the first node.

5. The shift register according to claim 4, wherein the first output module comprises a third switch transistor and a capacitor;
a gate of the third switch transistor is connected to the first node, a source of the third switch transistor is connected with the first clock signal, and a drain of the third switch transistor is connected to the signal output terminal;
the capacitor is connected between the gate and the drain of the third switch transistor.

6. The shift register according to claim 5, wherein the second output module comprises a fourth switch transistor, a fifth switch transistor and a sixth switch transistor;
a gate of the fourth switch transistor is connected with the second clock signal, a source of the fourth transistor is connected to the DC voltage source, and a drain of the fourth switch transistor is connected to the signal output terminal;
a gate of the fifth switch transistor is connected with the second clock signal, a source of the fifth switch transistor is connected to the DC voltage source, and a drain of the fifth switch transistor is connected to the second node;
a gate of the sixth switch transistor is connected to the second node, a source of the sixth switch transistor is connected to the DC voltage source, a drain of the sixth switch transistor is connected to the signal output terminal.

7. The shift register according to claim 6, wherein the first control sub-module comprises a seventh switch transistor;
a gate of the seventh switch transistor is connected to the second node, a source of the seventh switch transistor is connected to the DC voltage source, and a drain of the seventh switch transistor is connected to the first node.

8. The shift register according to claim 7, wherein the second control sub-module comprises an eighth switch transistor;
a gate of the eighth switch transistor is connected to the first node, a source of the eighth switch transistor is connected to the DC voltage source, a drain of the eighth switch transistor is connected to the second node.

9. The shift register according to claim 8, wherein the third control sub-module comprises a ninth switch transistor;
both a gate and a source of the ninth transistor are connected with the first clock signal, a drain of the ninth transistor is connected to the second node.

10. The shift register according to claim 9, wherein
when the voltage of the DC voltage source is a low level voltage, all the switch transistors are N type transistors; and
when the voltage of the DC voltage source is a high level voltage, all the switch transistors are P type transistors.

11. A driving method of a shift register according to claim 1, comprising:
at a first phase, the input module providing the first reference voltage to the first node under the control of the input signal; the first output module providing the first clock signal to the signal output terminal under the control of the first node; the second output module providing the voltage of the DC voltage source to the second node and the signal output terminal under the control of the second clock signal; the control module causing the voltage of the second node to be the second voltage under the control of the first node;
at a second phase, the first output module providing the first clock signal to the signal output terminal; the control module providing the first clock signal to the second node under the control of the first clock signal, and causing the voltage of the second node to be the second voltage when the voltage of the first node is the first voltage;
at a third phase, the reset module providing the second reference voltage to the first node under the control of the reset signal; the second output module providing the voltage of the DC voltage source to the second node and the signal output terminal under the control of the second clock signal;
at a fourth phase, the control module providing the first clock signal to the second node under the control of the first clock signal, and causing the voltage of the first node to be the second voltage when the voltage of the second node is the first voltage; the second output module providing the voltage of the DC voltage source to the signal output terminal under the control of the second node;
at a fifth phase, the second output module providing the voltage of the DC voltage source to the second node and the signal output terminal under the control of the second clock signal.

12. A gate driving circuit comprising multiple shift registers according to claim 1 which are connected in series; wherein
except the first stage of shift register, the signal output terminal of each stage of shift register inputs a reset signal to its adjacent previous stage of shift register;
except the last stage of shift register, the signal output terminal of each stage of shift register inputs an input signal to its adjacent next stage of shift register;
the input signal of the first stage of shift register is input by a frame start signal terminal, wherein
clock signals input into first clock signal terminals of two adjacent stages of shift register have opposite phases to each other, and clock signals input into second clock signal terminals of two adjacent stages of shift register units have opposite phases to each other.

13. The shift register according to claim 1, wherein the input module comprises a first switch transistor;
a gate of the first switch transistor is connected with the input signal, a source of the first switch transistor is connected with the first reference voltage, and a drain of the first switch transistor is connected to the first node.

14. The shift register according to claim 1, wherein the reset module comprises a second switch transistor;
a gate of the second switch transistor is connected with the reset signal, a source of the second switch transistor is connected with the second reference voltage, and a drain of the second switch transistor is connected to the first node.

15. The shift register according to claim 1, wherein the first output module comprises a third switch transistor and a capacitor;
a gate of the third switch transistor is connected to the first node, a source of the third switch transistor is connected with the first clock signal, and a drain of the third switch transistor is connected to the signal output terminal;
the capacitor is connected between the gate and the drain of the third switch transistor.

16. The shift register according to claim 1, wherein the second output module comprises a fourth switch transistor, a fifth switch transistor and a sixth switch transistor;
a gate of the fourth switch transistor is connected with the second clock signal, a source of the fourth transistor is connected to the DC voltage source, and a drain of the fourth switch transistor is connected to the signal output terminal;
a gate of the fifth switch transistor is connected with the second clock signal, a source of the fifth switch transistor is connected to the DC voltage source, and a drain of the fifth switch transistor is connected to the second node;
a gate of the sixth switch transistor is connected to the second node, a source of the sixth switch transistor is connected to the DC voltage source, a drain of the sixth switch transistor is connected to the signal output terminal.

17. The shift register according to claim 2, wherein the first control sub-module comprises a seventh switch transistor;
a gate of the seventh switch transistor is connected to the second node, a source of the seventh switch transistor is connected to the DC voltage source, and a drain of the seventh switch transistor is connected to the first node.

18. The shift register according to claim 2, wherein the second control sub-module comprises an eighth switch transistor;
a gate of the eighth switch transistor is connected to the first node, a source of the eighth switch transistor is connected to the DC voltage source, a drain of the eighth switch transistor is connected to the second node.

19. The shift register according to claim 2, wherein the third control sub-module comprises a ninth switch transistor;
both a gate and a source of the ninth transistor are connected with the first clock signal, a drain of the ninth transistor is connected to the second node.
